(19) United States
(12) Patent Application Publication
(10) Pub. No.: US 2013/0222686 A1
(43) Pub. Date: Aug. 29, 2013

(54) CAMERA MODULE, TERMINAL AND MANUFACTURING METHOD

(71) Applicant: Pantech Co., Ltd., (US)

(72) Inventor: Sun Woo BAEK, Seoul (KR)

(73) Assignee: Pantech Co., Ltd., Seoul (KR)

(21) Appl. No.: 13/748,940

(22) Filed: Jan. 24, 2013

(30) Foreign Application Priority Data
Feb. 29, 2012 (KR) 10-2012-0021381

(51) Int. Cl. H04N 5/225; H05K 3/34

(52) U.S. Cl. CPC H04N 5/2251; H05K 3/341
USPC 348/374; 29/832

(57) ABSTRACT

A terminal includes a first board including an accommodation portion, the accommodation portion being disposed in a first groove of the first board, and a camera module mounted in the accommodation portion. A method for manufacturing a terminal includes obtaining a first board including an accommodation portion, the accommodation portion being disposed in a first groove of the first board, obtaining a camera module to be mounted in the accommodation portion, and mounting the camera module in the accommodation portion.

### CROSS-REFERENCE TO RELATED APPLICATION

This application claims priority from and the benefit under 35 U.S.C. §119(a) of Korean Patent Application No. 10-2012-0021381, filed on Feb. 29, 2012, the entire disclosure of which is incorporated herein by reference for all purposes.

### BACKGROUND

1. Field

The following description relates to a camera module, a terminal including the same, and a manufacturing method thereof.

2. Discussion of the Background

With a tendency of a terminal to be designed with a reduced thickness, there may be more focus for the terminal and a manufacturing method thereof to be designed to dispose various components within a reduced amount of space.

FIG. 1 is a side view of a conventional camera module 10.

Referring to FIG. 1, the camera module 10 of a terminal may be manufactured to include a main body portion 11, which may be connected to a connector 13 with a flexible circuit board 15. The main body portion 11 may include a camera lens, an image sensor, and the like.

FIG. 2A is a perspective view of a board to which the conventional camera module 10 is mounted on a terminal. FIG. 2B is a side view of the flexible circuit board to which the conventional cameral module 10 is mounted as illustrated in FIG. 2A.

Referring to FIG. 2A and FIG. 2B, in order to mount the camera module 10, the connector 13 of the camera module 10 may be manually or mechanically assembled to a socket 21 provided on a first board 20.

Accordingly, it may be difficult to dispose components other than the camera module 10 within the periphery of the assembly position of the camera module 10 and the peripheral components. More particularly, an electric signal may be moved through the flexible circuit board 15 with a thin circuit pattern. Accordingly, a part that may be vulnerable to noise and other interference may be generated. Thus, a sufficient margin space has to be ensured in order to exclude or minimize interference on the camera module that may be generated based on interference between components in the terminal.

In addition, as the camera module 10 is mounted to the first board 20, a space occupied by the first board may be increased by a height HO with respect to the main body portion 11 in the terminal. Accordingly, the space in which the components of the terminal are designed to be mounted may be narrowed, such that a degree of design freedom may be limited. More specifically, since mounting the camera module 10 may occupy a large amount of space, the amount of thickness and size that may be reduced in the terminal may be restricted. Accordingly, there may be a problem in that merchantable quality (i.e., size and thickness of the terminal) of the terminal may be degraded.

In addition, the main body portion 11, the flexible circuit board 15, and the connector 13 of the camera module 10 may be separately manufactured, such that there may be a problem in that production costs of the mobile communication terminals are increased. In addition, since the connector 13 may be used to connect to the first board 20, contact failure of the connector 13 or fastening failure of the connector 13 may occur.

In addition, since the process of assembling the camera module 10 to the first board 20 may be included in the manufacturing process, the overall manufacturing process may become more complex and additional costs may be incurred. In addition, failure rate in mounting the camera module 10 to the first board 20 may reduce the production yield of the terminals including the camera module 10.

In order to solve the above problems, various studies have been carried out on designing of a terminal and a manufacturing method capable of mounting the camera module 10 to reduce the mounting space utilized by the camera module 10.

### SUMMARY

Exemplary embodiments of the present invention provide a camera module, a terminal including the same, and a manufacturing method thereof.

Additional features of the invention will be set forth in the description which follows, and in part will be apparent from the description, or may be learned by practice of the invention.

Exemplary embodiments of the present invention provide a terminal including a first board including an accommodation portion, the accommodation portion being disposed in a first groove of the first board, and a camera module mounted in the accommodation portion.

Exemplary embodiments of the present invention provide a method for manufacturing a terminal including obtaining a first board including an accommodation portion, the accommodation portion being disposed in a first groove of the first board, obtaining a camera module mounted in the accommodation portion, and mounting the camera module in the accommodation portion.

Exemplary embodiments of the present invention provide a terminal including a first board including an accommodation portion and a first electrode, the accommodation portion being disposed in a groove of the first board, a camera module including a second electrode mounted in the accommodation portion, and a lead to connect the first electrode of the first board to the second electrode of the camera module.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a side view of a conventional camera module.

FIG. 2A is a perspective view of a board to which the conventional camera module is mounted on a terminal. FIG. 2B is a side view of the flexible circuit board to which the conventional cameral module 10 is mounted as illustrated in FIG. 2A.

FIG. 3 is a cross-sectional view illustrating a first board with a camera module mounted thereon in a terminal according to an exemplary embodiment of the present invention.

FIG. 4 is cross-sectional views illustrating a first board with a camera module mounted thereon at various mounting depths in a terminal according to an exemplary embodiment of the present invention.

FIG. 5 is a cross-sectional view of a first board with a camera module mounted thereon in a terminal according to an exemplary embodiment of the present invention.

FIG. 6 is a plan view illustrating a process of mounting a camera module to a first board in a terminal according to an exemplary embodiment of the present invention.

FIG. 7 is a diagram illustrating a cross-section of a first board mounting the camera module of FIG. 6.

FIG. 8 is a partial enlarged view of the cross-section of the first board of FIG. 7.

FIG. 9 is a cross-sectional view illustrating a camera module mounted on a first board of a terminal according to an exemplary embodiment of the present invention.

FIG. 10 is a flowchart illustrating a manufacturing method of a terminal according to an exemplary embodiment of the present invention.

FIG. 11 is a flowchart illustrating a manufacturing method of a terminal according to an exemplary embodiment of the present invention.

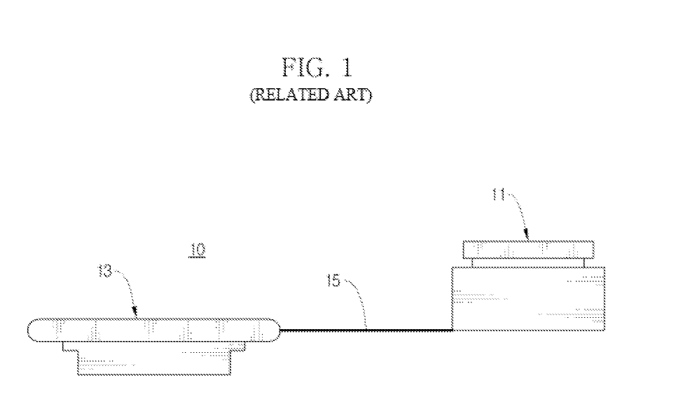

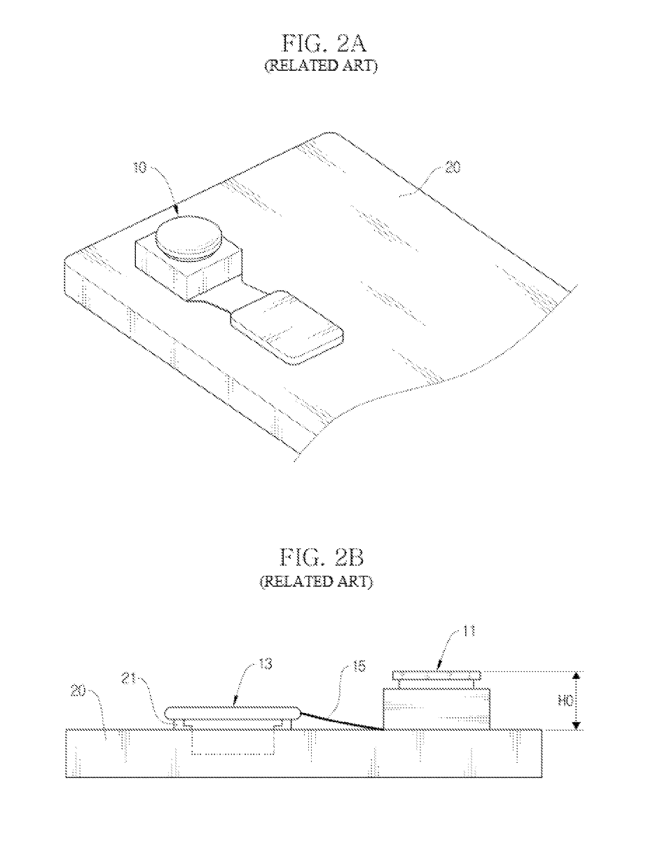

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. It will be understood that for the purposes of this disclosure, “at least one of X, Y, and Z” can be construed as X only, Y only, Z only, or any combination of two or more items X, Y, and Z (e.g., XYZ, XZ, XYY, YZ, ZZ). Throughout the drawings and the detailed description, unless otherwise described, the same drawing reference numerals are understood to refer to the same elements, features, and structures. The relative size and depiction of these elements may be exaggerated for clarity.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Although some features may be described with respect to individual exemplary embodiments, aspects need not be limited thereto such that features from one or more exemplary embodiments may be combinable with other features from one or more exemplary embodiments.

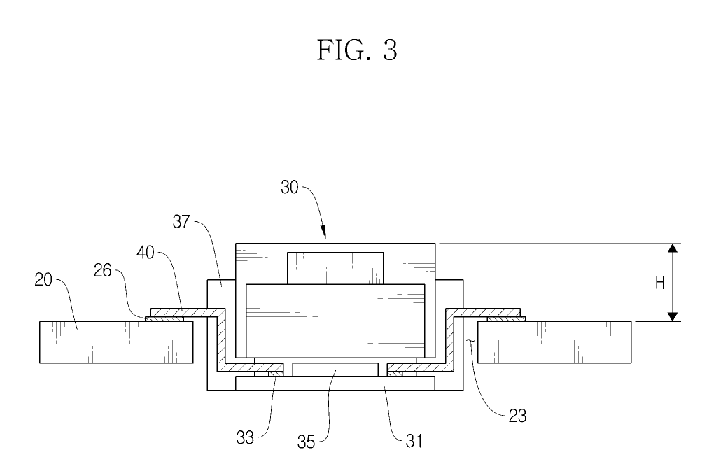

FIG. 3 is a cross-sectional view illustrating a first board with a camera module mounted thereon in a terminal according to an exemplary embodiment of the present invention.

Referring to FIG. 3, the terminal includes a first board 20 and a camera module 30. The camera module 30 connects to the first board 20 via a first lead 40. The first board 20 connects to a first portion of the first lead 40 via a first electrode 26, and the camera module 30 connects to a second portion of the first lead 40 via a second electrode 33. The camera module 30 may be mounted or inserted within an accommodation portion 23, which may be included in the first board 20. According to exemplary embodiments, the terminal may include a mobile communication device, a personal computer (PC), a tablet, a smart phone, and the like.

The first board 20 may refer to a board or a substrate on which the camera module 30 is mounted. Further, a printed circuit board in which various external components other than the camera module 30 may be mounted on the first board 20 as well.

The accommodation portion 23 may be an opening, a groove, or a cavity provided on the first board 20. One or more first electrodes 26 may be formed on the first board 20 to accommodate mounting of one or more components.

The accommodation portion 23 may be formed to have a through-hole shape, which may penetrate the first board 20. However, aspects of the invention are not limited thereto, such that the accommodation portion 23 may have a groove shape, a partial cavity, and the like. The camera module 30 may be inserted or mounted in the accommodation portion 23. Accordingly, a mounting height H of the camera module 30 may be lower than a mounting height of a conventional mobile communication terminal.

The mounting height may refer to a height of a component, such as the camera module 30, protruding from a top surface of the first board 20 when the component is mounted in the first board 20.

When the camera module 30 is inserted in or mounted on the accommodation portion 23, the mounting height of the camera module 30 may be reduced by an insertion depth. The insertion depth may refer to a distance from a top surface of the first board 20 to a bottom surface of the accommodation portion 23 or a bottom surface of the camera module 30, but is not limited thereto. For example, the insertion depth may refer to a distance from a portion of the first board 20 to a portion of the camera portion 30. Therefore, the mounting height of the camera module 30, which may protrude higher than other components from the first board 20, may be reduced to reduce an overall height and volume of the terminal. The height of the first board 20, which may have various components mounted thereon, inclusive of the camera module 30, may be related with an overall thickness of the terminal. Accordingly, merchantable quality of the terminal may be increased by reducing the overall thickness of the terminal.

The camera module 30 includes a second board 31 to accommodate a camera unit of the camera module 30. The camera module 30 further includes a second electrode 33, an image sensor 35, and a housing 37, in which the second board 31 is accommodated. One or more leads 40 may penetrate the housing 37 to be electrically connected to the second electrode 33. However, aspects of the invention are not limited thereto, such that the camera module 30 may include additional components, which may not be illustrated in FIG. 3.

More specifically, the second board 31 is disposed at a lower portion of the housing 37. Further, a plurality of second electrodes 33 is disposed on the second board 31. However, aspects of the invention are not limited thereto, such that at least one of the second board 31, the second electrodes 33, and the portions of the first lead 40 may be disposed outside of the camera module 30. Further, the accommodation portion 23 of the first board 20 may be a lower surface portion of the first board 20, on which at least one of the second board 31, the second electrodes 33, and the portions of the first lead 40 may be disposed.

The lead 40 may be a terminal used to mount the camera module in the first board 20. The lead 40 may be formed to be electrically connected to the second electrode 33 of the camera module 30. Accordingly, when the camera module 30 is mounted in the first board 20, the lead 40 may be formed to electrically connect the first electrode 26 of the first board 20 to the second electrode 33.

Further, the lead 40 may be formed by inserting a molding together with the housing 37. More specifically, a process of forming the lead 40 may be added to the molding process of the housing 37. Accordingly, the lead 40 may be formed during the same process the housing 37 is formed, and the overall manufacturing costs of the terminal may be reduced. In the conventional terminal, a connector, a flexible circuit board, and other components may be formed to mount a camera module, which may increase the number of components and the production costs of the camera module. However, according to exemplary embodiment of the present invention, because only the lead 40 may be added to mount the camera module 30, the production process of the terminal may become more simplified, and production costs associated with the manufacturing of the terminal may be reduced.

In addition, one or more leads 40 may be connected to the first electrode 26. More specifically, the one or more leads 40 may be connected to the first electrode 26 of the first board 20, a ground terminal, and other relevant components.

In addition, the second board 31 may be a rigid board or a flexible board. In the conventional terminal, the second board may be formed as a flexible board to extend the flexible circuit board 15, which may be associated with high manufacturing costs. However, according to exemplary embodiments of the present invention, the second board may not employ a connector structure, which may allow the second board to be manufactured from a rigid board. Since the rigid boards may be cheaper than a flexible board, the manufacturing costs may be reduced, and the degree of design freedom of the second board may be improved.

The camera module 30 may be mounted in the first board 20 through a reflow process or a comparable process. In addition, the camera module 30 may be mounted on the first board 20 through an insertion method. Further, the camera module 30 may be supported on the first board 20 by the first lead 40, but it is not limited thereto. The mounting method will be described in more detail below.

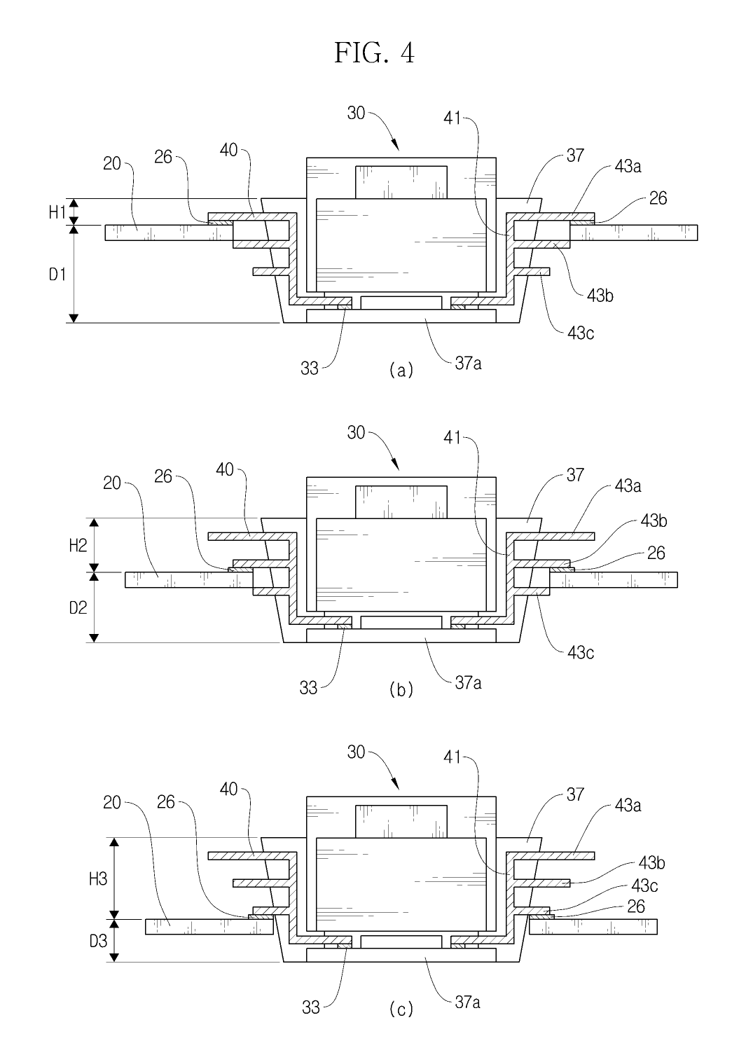

FIG. 4 is cross-sectional views illustrating a first board with a camera module 30 mounted thereon at various mounting depths in a terminal according to an exemplary embodiment of the present invention.

Referring to (a), (b), and (c) of FIG. 4, the lead 40 may include a main lead 41, which may be connected to the second electrode 33 and penetrate through the housing 37, and at least one of a first sub-lead 43a, a second sub-lead 43b, and a third sub-lead 43c. The first sub-lead 43a, the second sub-lead 43b, and the third sub-lead 43c may extend outward from the housing 37, and may be disposed apart from each other at predetermined distances in a vertical direction of the housing 37.

Since the first sub-lead 43a, the second sub-lead 43b, and the third sub-lead 43c may be disposed apart at predetermined distances from each other along a vertical direction of the housing 37, the first electrode 26 may be connected to any one of the first sub-lead 43a, the second sub-lead 43b, and the third sub-lead 43c along insertion depths (e.g., insertion depth D1), which may be set in advance. The distance between the respective sub-leads may provide a groove or a sub-groove in which a portion of the first board 20 may be disposed to contact the first electrode 26 disposed on at least one of the sub-leads. More specifically, since the first sub-lead 43a is extended farther from the camera module 30 than the second sub-lead 43b, for example, a portion of the first board 20 may extend towards an end portion, such as a vertical edge, of the second sub-lead 43b, such that a top portion of the first board 20 may come in contact with the first sub-lead 43a. More specifically, the first board 20 may extend towards one of the lower sub-leads (e.g., second sub-lead 43b or third sub-lead 43c) to contact a surface, such as a bottom surface, of the upper sub-lead (e.g., first sub-lead 43a). However, aspects of the invention are not limited thereto, such that a portion of the first board 20 may be inserted in one of the grooves provided between the respective sub-leads to contact the first electrode 26.

More specifically, if the first electrode 26 is connected to the first sub-lead 43a, an insertion depth D1 and a mounting height H1 may be provided as shown in (a) of FIG. 4. If the first electrode 26 is connected to the second sub-lead 43b, an insertion depth D2 and a mounting height H2 may be provided as shown in (b) of FIG. 4. If the first electrode 26 is connected to the third sub-lead 43c, an insertion depth D3 and a mounting height H3 may be provided as shown in (c) of FIG. 4.

Accordingly, as the first electrode 26 moves from the first sub-lead 43a downwards towards the third sub-lead 43c, which is closer to a lower surface 37a of the housing 37 from among the first sub-leads 43a, the second sub-lead 43b, the third sub-lead 43c, the first insertion depth D1 may be reduced to the second insertion depth D2 before reducing further to an insertion depth D3. Correspondingly, a mounting height may be increased from the mounting height H1, to the mounting height H2, and then to the mounting height H3.

The insertion depth may refer to a depth by which the component may be inserted into the first board 20. The insertion depth may further indicate a distance from a top surface of the first board 20 to the lower surface 37a of the housing 37 of the cameral module 30.

Therefore, a user may select a sub-lead among the first sub-lead 43a, the second sub-lead 43b, and the third sub-lead 43c to have a corresponding first mounting height H1, second mounting height H2, or third mounting height H3. The selected sub-lead may connect to the first electrode 26.

In addition, the first sub-lead 43a, the second sub-lead 43b, and the third sub-lead 43c may be formed so that the lengths extending outward may be reduced toward the lower surface 37a of the housing 37 as shown in FIG. 4. More specifically, the first sub-lead 43a may be extended outwards in a longer length than the second sub-lead 43b, and the third sub-lead 43c. The second sub-lead 43b may be extended outwards in a longer length than the third sub-lead 43c. Accordingly, when the first electrode 26 is connected to at least one of the first sub-lead 43a, the second sub-lead 43b, and the third sub-lead 43c, the sub-leads in the direction toward the lower surface 37a of the housing 37 may not interfere with the insertion of the camera module 30.

In addition, the sub-leads, which may not be connected among the first sub-lead 43a, the second sub-lead 43b, and the third sub-lead 43c may be used to dissipate heat generated by the camera module 30. In an example, one or more of the respective sub-leads may be made of a metal material with heat dissipating characteristics.

More specifically, referring to FIG. 4, the lead 40 may include the main lead 41, which may be connected to the second electrode 33. The main lead 41 may penetrate through the inside of the housing 37, and the first sub-lead 43a, the second sub-lead 43b, and the third sub-lead 43c, which may be connected to the main lead 41, extend outward from the housing 37. The first sub-lead 43a, the second sub-lead 43b, and the third sub-lead 43c may be disposed at the predetermined distances along a vertical direction of the housing 37.

The first electrode 26 may be connected to at least one of the first sub-lead 43a, the second sub-lead 43b, and the third sub-lead 43c along a first insertion depth D1, a second insertion depth D2, and a third insertion depth D3, respectively.

The main lead 41 extends from a bottom portion of the camera module 30 and connects to the second electrode 33, which is disposed on the lower surface 37a of the housing 37. The second electrode 33 is disposed adjacent to the image sensor 35. The main lead 41 includes subportions that extend away from the camera module 30 in parallel and in increasing distance from bottom to the top (i.e., the subportion nearer to the bottom of the cameral module 30 extends a smaller distance away from the camera module 30 than the subportion nearer the top of the camera module 30). Further, the subportions are spaced to receive or contact edges of the first board 20 at the accommodation portion therebetween. However, aspects need not be limited thereto, such that the main lead 41 need not extend from the bottom of the camera module 30 but may be connected to the second electrode 33 anywhere within the camera module 30.

In (a) of FIG. 4, (a) illustrates an exemplary embodiment in which the first electrode 26 is connected to the first sub-lead 43a to provide a first insertion depth D1 and a first mounting height H1.

When the first electrode 26 is connected to the first sub-lead 43a, which may be positioned farthest from the lower surface 37a of the housing 37 among the first sub-lead 43a, the second sub-lead 43b, and the third sub-lead 43c, the camera module 30 may be inserted into an accommodation portion 23 of the mobile first board 20 so that a distance from the first electrode 26 to the bottom of the housing 37 provides the first insertion depth D1. Further, the distance from the first electrode 26 to the top of the housing 37 may correspondingly provide the first mounting height H1, which may be the shortest mounting height H1 among the (a) of FIG. 4, (b) of FIG. 4, and (c) of FIG. 4.

When the mounting height of the camera module 30 is reduced, and a reduction in thickness of the first board of the terminal may be achievable, which may contribute in a reduction in the overall thickness of the terminal.

Referring to (a) of FIG. 4, the first board 20 having a lower height than that of the camera module 30 is illustrated. However, aspects of the invention are not limited thereto, such that the first board 20 may be formed to have a higher height than that of the camera module 30 so that the camera module 30 may recede into the accommodation portion of the first board 20.

In (b) of FIG. 4, (b) illustrates an exemplary embodiment in which the first electrode 26 is connected to the second sub-lead 43b to provide a second insertion depth D2, and a second mounting height H2.

When the first electrode 26 is connected to the second sub-lead 43b, which may be positioned between the first sub-lead 43a and the third sub-lead 43c among the first sub-lead 43a, the second sub-lead 43b, and the third sub-lead 43c, the camera module 30 may be inserted into an accommodation portion of the first board 20 so that a distance from the first electrode 26 to the bottom of the housing 37 provides the second insertion depth D2, which may be smaller than the first insertion depth D1. Further, the distance from the first electrode 26 to the top of the housing 37 may correspondingly provide the second mounting height H2, which may be greater than the first mounting height H1.

In (c) of FIG. 4, (c) illustrates an exemplary embodiment in which the first electrode 26 is connected to the third sub-lead 43c to provide a third insertion depth D3 and a third mounting height H3.

When the first electrode 26 is connected to the third sub-lead 43c, which may be positioned closest to the lower surface 37a of the housing 37 among the first sub-lead 43a, the second sub-lead 43b, and the third sub-lead 43c, the camera module 30 may be inserted into an accommodation portion of the first board 20 so that a distance from the first electrode 26 to the bottom of the housing 37 provides the shortest depth or the third insertion depth D3. Further, the distance from the first electrode 26 to the top of the housing 37 may correspondingly provide the longest mounting depth H3.

Referring to (a) of FIG. 4, (b) of FIG. 4, and (c) of FIG. 4, the first insertion depth D1 may be largest, the second insertion depth D2 may be the second largest, and the third insertion depth D3 may be the smallest. However, contrary to the insertion depths, the first mounting height H1 may be the smallest, the second mounting height H2 may be the second smallest, and third mounting height H3 may be the largest.

More specifically, the mounting height may be lowered as the insertion depth is deepened. The insertion depth may be controlled by selecting the sub-lead of the camera module 30 to be connected to the first electrode 26, which may also control the mounting height.

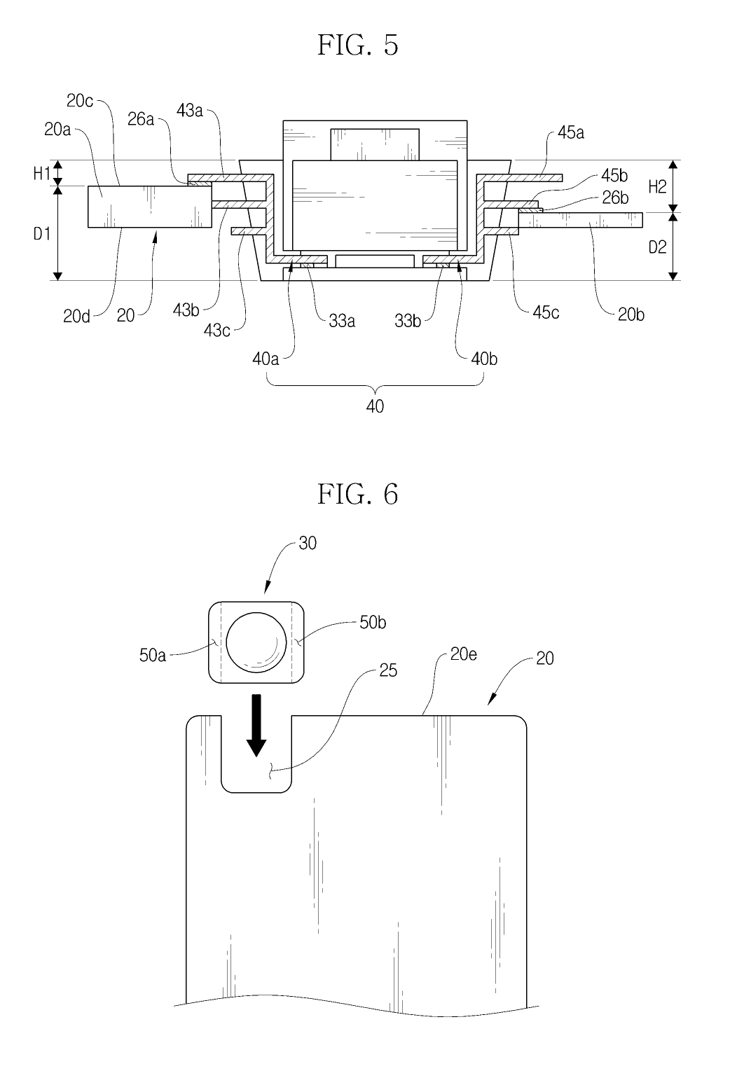

FIG. 5 is a cross-sectional view of a first board with a camera module mounted thereon in a terminal according to an exemplary embodiment of the present invention.

Referring to FIG. 5, the first board 20 includes a first board unit 20a, and a second board unit 20b having a different thickness. The camera module 30 may be joined so that the first boarding unit 20a and the second board units 20b have different mounting heights.

The first board unit 20a and the second board unit 20b may respectively have one or more first electrodes 26a and first electrode 26b. The lead 40 of the camera module 30 may include a first lead 40a and a second lead 40b, which may extend in opposite directions from the housing 37. The first lead 40a and the second lead 40b may include a first main lead 41a and a second main lead 41b, which may respectively be connected to the second electrode 33a and the second electrode 33b. The first main lead 41a and the second main lead 41b may penetrate through the housing 37. At least one of the sub-leads, which may be connected to at least one of the first main lead 41a and the second main lead 41b, extend outward from the housing 37, may be disposed apart at predetermined distances along a vertical direction of the housing 37.

The first electrode 26a of the first board unit 20a may be connected to the first sub-lead 43a of the first lead 40a to provide the first insertion depth D1. The first electrode 26b of the second board unit 20b may be connected to the second sub-lead 45b of the second lead 40b to provide the second insertion depth D2, which may be different from the first insertion depth D1.

As shown in FIG. 5, the first electrode 26a of the first board unit 20a is connected to the first sub-lead 43a of the first lead 40a to provide the first insertion depth D1 and a corresponding first mounting height H1. In addition, the first electrode 26b of the second board unit 20b is connected to the second sub-lead 45b of the second lead 40b to provide the second insertion depth D2 and a corresponding second mounting height H2. Accordingly, different sub-leads may accommodate varying sizes or thickness of boards, and the different lengths of the sub-leads may allow the thicker boards to extend towards an end portion of a lower sub-lead to connect to an electrode disposed on a surface of an upper sub-lead. The thinner boards may be inserted into a groove provided between sub-leads such that the board may contact an electrode disposed on at least one of the respective sub-leads, if not the sub-lead itself. However, aspects of the invention are not limited thereto, such that the structure of a board in which the camera module is disposed need not be symmetric, such that various portions of the board may have varying thickness or shape. Further, different subportions of the electrodes may be connected to different portions of the board.

In FIG. 5, the first mounting height H1 may be smaller than the second mounting height H2. However, aspects of the invention are not limited thereto, such that the second mounting height H2 may be smaller than the first mounting height H1. In addition, while it is described that the first insertion depth D1 is greater than the second insertion depth D2, the aspects of the invention are not limited thereto, such that the second insertion depth D2 may be greater than the first insertion depth D2.

FIG. 6 is a plan view illustrating a process of mounting a camera module to a first board in a terminal according to an exemplary embodiment of the present invention.

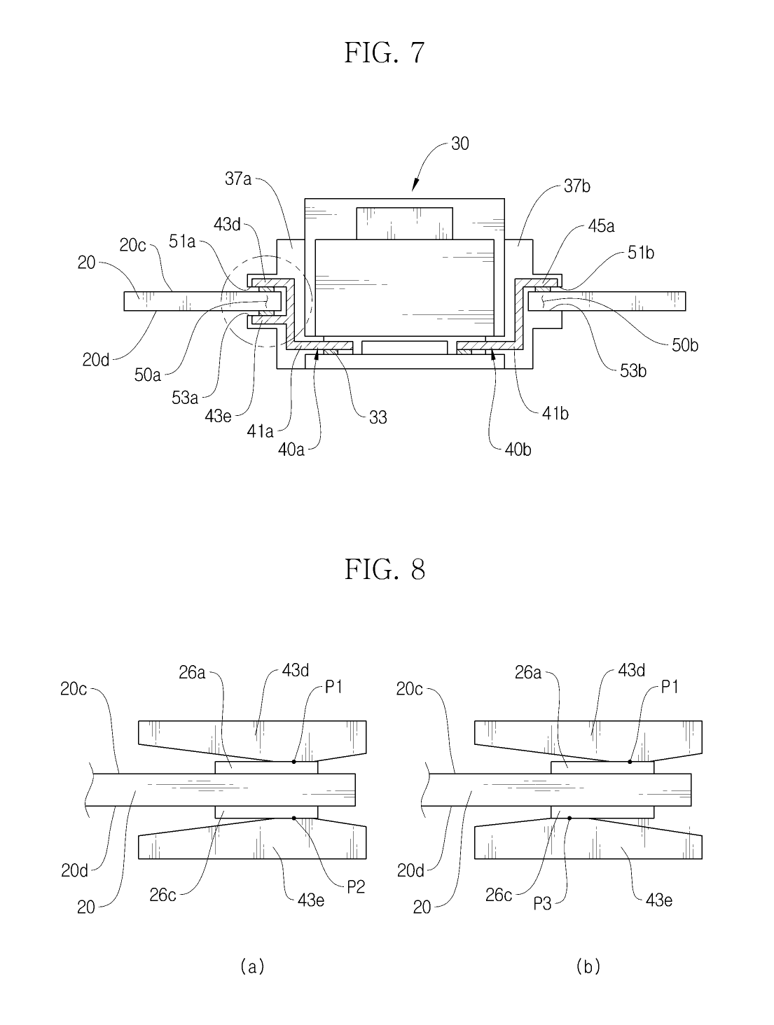

FIG. 7 is a diagram illustrating a cross-section of a first board mounting the camera module of FIG. 6.

Referring to FIG. 6 and FIG. 7, the accommodation portion 25 may be formed on a face 20e of the first board 20. The face may be a side face of the first board 20. The housing includes a first side face 37a and a second side face 37b. The first side face 37a and the second side face 37b include a first groove 50a and a second groove 50b, respectively, which may be formed to be fitted into the accommodation portion 25. The leads may be formed to be drawn to or inserted into the first groove 50a and the second groove 50b. The leads may be connected to the first electrode. Although the accommodation portion 25 is illustrated as a cavity in the first board 20 that extends therethrough, aspects of the invention are not limited thereto, such that the accommodation portion 25 may be a recessed portion of the first board 20, which may be used to mount the camera module 30.

Inside the first groove 50a and the second groove 50b, a first upper surface 51a and a second upper surface 51b facing an upper surface of the first board 20, and a first lower surface 53a and a second lower surface 53b facing a lower surface of the first board 20 may be formed. The leads may be formed to be drawn to at least one of the first upper surface 51a, the second upper surface 51b, the first lower surface 53a, and the second lower surface 53b. The first electrode may be formed at a position facing at least one of the first upper surface 51a and the second upper surface 51b, or at least one of the first lower surface 53a and the second lower surface 53b.

More specifically, referring to FIG. 6, FIG. 7, and FIG. 8, in the first board 20, the accommodation portion 25 may be formed on the side face 20e of the first board 20. In addition, the first electrode 26a and the first electrode 26b may be formed on both side faces of the accommodation portion 25, or at positions where the first board 20 comes in contact with the first groove 50a and the second groove 50b.

In addition, the housing of the camera module 30 includes the first side face 37a and the second side face 37b, which may be opposing each other. The first groove 50a and the second groove 50b may be disposed on the first side surface 37a and the second side face 37b, respectively, to fit the camera module 30 to the accommodation portion 25 of the first board 20. The first groove 50a and the second groove 50b may include the first upper surface 51a and the second upper surface 51b, respectively, and the first lower surface 53a and the second lower surface 53b. At least one of the first upper surface 51a and the second upper surface 51b may contact an upper surface 20c of the first board 20, and at least one of the first lower surface 53a and the second lower surface 53b may contact a lower surface 20d of the first board 20.

The lead 40 of the camera module 30 may include the first lead 40a drawn to the first side face 37a, and the second lead 40b drawn to the second side face 37b. Referring to FIG. 7, the first lead 40a may include a first sub-lead 43d, a second sub-lead 43e, and a first main lead 41a. The second lead 40b may include a third sub-lead 45a, and a second main lead 41b. The first lead 40a and second lead 40b may be connected to the second electrode 33, and the first main lead 41a and the second main lead 41b may penetrate through the housing, including the first side face 37a and the second side face 37b. Further, one or more sub-leads among the first sub-lead 43d, the second sub-lead 43e, and the third sub-lead 45a may be drawn to one or more of the first upper surface 51a, the second upper surface 51b, the first lower surface 53a and the second lower surface 53b.

Referring to FIG. 7, the first lead 40a may include the first sub-lead 43d and the second sub-lead 43e, which may be respectively drawn to the first surface 51a and the second surface 53a. The second lead 40b may include the first sub-lead 45a, which may be drawn to the second upper surface 51b.

The camera module 30 may be fitted to the accommodation portion 25 of the first board 20. The camera module 30 may be mounted to the first board 20 such that the first board 20 has may fit within the first groove 50a and the second groove 50b of the camera module 30.

In addition, the sub-leads may be drawn to the first upper surface 51a and the second upper surface, 51b or the first lower surface 53a and the second lower surface 53b of the first groove 50a and the second groove 50b. Since the first electrode 26 may be disposed in the first board 20 to contact at least one of the first groove 50a and the second groove 50b, the sub-leads may be connected to the first electrode when the camera module 30 is inserted into the accommodation portion 25 of the first board 20.

The first electrode and the second electrode may be electrically connected by inserting the camera module 30 to the accommodation portion 25 of the first board 20 without additional mounting process. The camera module 30 may be fastened or connected to the first board 20 through a manual or an automatic assembly method. In addition, since the camera module 30 may be manufactured to be inserted to the accommodation portion of the first board 20, the mounting height of the camera module 30 may be reduced when inserted into the accommodation portion the first board 20. Accordingly, the thickness contributed by the camera module 30 to the overall thickness of the terminal may be reduced. In addition, if the camera module 30 is performed using the insertion method, maintenance and replacement of the camera module 30 may be more accessible.

FIG. 8A and FIG. 8B are partial enlarged view of the cross-section of the first board of FIG. 7.

Referring to FIG. 8A and FIG. 8B, a contact structure to ensure an electrical connection between the lead of the camera module 30 and the first electrode may be provided during the insertion operation.

The first electrode may be formed and disposed to have one or more contact points with the lead.

More specifically, to more reliably secure the electrical connection between the lead and the first electrode, at least one of the sub-leads may have shapes bent toward a first upper electrode 26a and a first lower electrode 26c and may form the contact points with the first electrode. Accordingly, the electrical connection between the camera module 30 and the first board 20 may be ensured by the insertion operation. In addition, to prevent or reduce the likelihood of the contact failure, additional contact points between the sub-leads and the first electrodes may be formed.

Referring to (a) of FIG. 8, inside the grooves, which may be a sliding groove, the first upper surface 51a, which may face an upper surface 20c of the first board 20, may come in contact with the first upper electrode 26a facing the first upper surface 51a at a first contact point P1. The first lower surface 53a, which may face a lower surface 20d of the first board 20, may come in contact with the first electrode facing the first lower surface 53a at a second contact point P2. The first contact point P1 and the second contact point P2 may be vertically aligned with respect to the first board 20.

More specifically, the first contact point P1 may refer to a location where the first upper electrode 26a disposed on the upper surface 20c of the first board 20, and the first sub-lead 43d, which may be the sub-lead drawn to the first upper surface 51a, comes in contact with each other. The second contact point P2 may refer to a location where the first lower electrode 26c disposed on the lower surface 20d of the first board 20 and the second sub-lead 43e, which may be the sub-lead drawn to the first lower surface 53a, comes in contact with each other. The first contact point P1 and the second contact point P2 may be vertically aligned with respect to the first board 20.

Since the first contact point P1 and the second contact point P2 may be provided by the bent sub-leads disposed in a vertical direction with respect to the first board 20, the first contact point P1 and the second contact point P2 may provide some pressure to the first board 20 from both directions. The exerted pressure may provide a more secure connection between the sub-lead and the first board 20, thereby preventing or reducing a likelihood of an electrical connection failure.

Referring to (b) of FIG. 8, inside the grooves, the first upper surface 51a, which may face an upper surface 20c of the first board 20, may come in contact with the first upper electrode 26a facing the first upper surface 51a at first contact point P1. The second surface 53a, which may face a lower surface 20d of the first board 20, may come in contact with the first electrode facing the first lower surface 53a at a third contact point P3. The first contact point P1 and the third contact point P3 may not be vertically aligned with respect to the first board 20.

More specifically, the first contact point P1 may refer to a location where the first upper electrode 26a formed on the upper surface 20c of the first board 20, and the first sub-lead 43d, which may be the sub-lead drawn to the first upper surface 51a, come in contact with each other. The third contact point P3 may refer to a location where the first lower electrode 26c disposed on the lower surface 20d of the first board and the second sub-lead 43e, which may be the sub-lead drawn to the first lower surface 53a, comes in contact with each other. The first contact point P1 and the third contact point P3 may not be vertically aligned with respect to the first board 20.

Although the first contact point P1 and the third contact point P3 may be formed by the bent sub-leads, which may not be vertically aligned with respect to the first board 20, the sub-lead and the first board 20 may not be separated and be electrically connected.

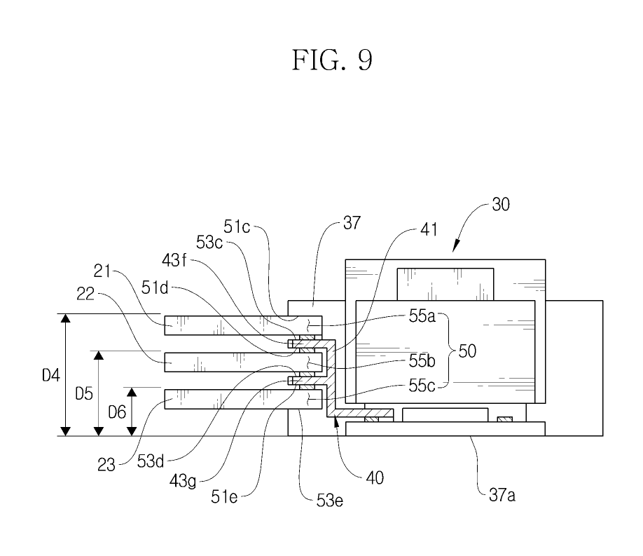

FIG. 9 is a cross-sectional view illustrating a camera module mounted on a first board of a terminal according to an exemplary embodiment of the present invention.

Referring to FIG. 9, the grooves include a first sub-groove 55a, a second sub-groove 55b, and a third sub-groove 55c, which may be disposed apart at predetermined distances along a vertical direction of the housing 37. The lead 40 may be formed and disposed between the first sub-groove 55a, the second sub-groove 55b, and the third sub-groove 55c to be connected to the first electrode 26.

The first sub-groove 55a, the second sub-groove 55b, and the third sub-groove 55c may include a first upper surface 51c, a second upper surface 51d, a third upper surface 51e, a first lower surface 53c, a second lower surface 53d, and a third lower surface 53e. The first sub-groove 55a, the second sub-groove 55b, and the third sub-groove 55c may be formed to face the upper and lower surfaces of the first board. The lead may include the main lead 41 penetrating through the inside of the housing 37 and multiple sub-leads, including a first sub-lead 43f and a second sub-lead 43g, drawn to the first upper surface 51c, the second upper Surface 51d, the third upper surface 51e, the first lower surface 53c, the second lower surface 53d, and the third lower surface 53e. However, aspects of the invention are not limited thereto, such that a number of grooves can be less than three or more than three. Further, the number of sub-leads is not limited to two.

Portions of the lead 40 disposed between the first sub-groove 55a, the second sub-groove 55b, and the third sub-groove 55c may be connected to the first electrode 26 along insertion depths.

Referring to FIG. 9, the groove 50 includes the first sub-groove 55a, the second sub-groove 55b, and the third sub-groove 55c. The first sub-groove 55a, the second sub-groove 55b, and the third sub-groove 55c may respectively include the first upper surface 51c, the second upper surface 51d, the third upper surface 51e, the first lower surface 53c, the second lower surface 53d, and the third lower surface 53e, which may be disposed to face an upper surface and a lower surface of a board. More specifically, referring to FIG. 9, a first board 21 faces the first upper surface 51c and the first lower surface 53c, a second board 22 faces the second upper surface 51d and the second lower surface 53d, and a third board 23 faces the third upper surface 51e and the third lower surface 53e. Although three boards are illustrated as being inserted into the provided sub-grooves, aspects of the invention are not limited thereto, such that one or two boards may be used to be inserted in the sub-grooves. Further, at least one of the provided boards may connect with a sub-lead without being inserted into the provided sub-grooves.

Each of the first sub-groove 55a, the second sub-groove 55b, and the third sub-groove 55c may be disposed so that the first sub-lead 43f and the second sub-lead 43g are exposed to at least one of the first upper surface 51c, the second upper surface 51d, the third upper surface 51e, the first lower surface 53c, the second lower surface 53d, and the third lower surface 53e. At least one of the first board 21, the second board 22, and the third board 23 may be inserted into at least one of the first sub-groove 55a, the second sub-groove 55b, and the third sub-groove 55c along the insertion depths.

The insertion depth may be reduced as the first board 20 is connected to a sub-groove, which may be closest to the lower surface 37a of the camera module 30 among the first sub-groove 55a, the second sub-groove 55b, and the third sub-groove 55c, and the mounting height may correspondingly be increased.

Referring to FIG. 9, the camera module 30 has the first groove 55a, the second groove 55b, and the third groove 55c in order and in a direction toward the lower surface 37a from an upper surface of the camera module 30.

The first electrode may be disposed on an upper surface or a lower surface of a board, or on both the upper surface and the lower surface of the respective board.

Referring to FIG. 9, the first board 21 may be inserted into the first sub-groove 55a. The first electrode may be disposed on the lower surface of the first board 20 and be connected to the first sub-lead 43f drawn to the first groove 55a.

In addition, when the second board 22 is inserted into the second sub-groove 55b, the first electrode may be formed on both the upper surface and the lower surface of the second board 22. Further, the first electrode may be connected to the first sub-lead 43f and the second sub-lead 43g, which may be drawn to the second groove 55b.

In addition, when the third board 23 is inserted into the third sub-groove 55c, the first electrode may be formed on the upper surface of the third board 23. Further, the first electrode may be connected to the second sub-lead 43g, which may be drawn to the third groove 55c.

During insertion of the first board 21, the second board 22, and the third board 23 into the sub-grooves, a fourth insertion depth D4, a fifth insertion depth D5, and a sixth insertion depth D6 are provided. The insertion depths are provided from the largest to the smallest in the order of the fourth insertion depth D4, the fifth insertion depth D5, and the sixth insertion depth D6. Thus, the mounting heights may be increased in the order of the first groove 55a, the second groove 55b, and the third groove 55c.

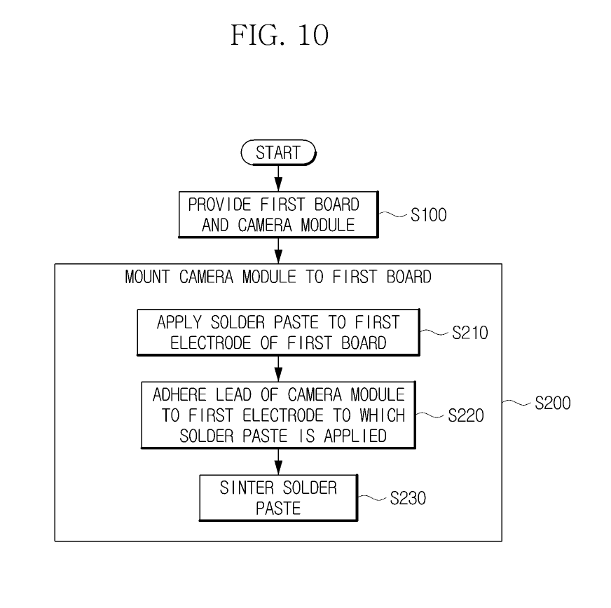

FIG. 10 is a flowchart illustrating a manufacturing method of a terminal according to an exemplary embodiment of the present invention. A method of manufacturing a terminal is as follows.

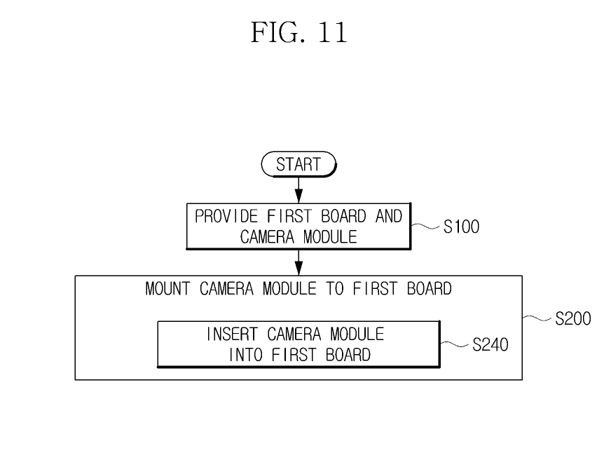

Referring to FIG. 10 and FIG. 11, the method of manufacturing a terminal may, in operation S100, provide a first board having an accommodation portion and at least one first electrode for connecting to a camera module, and the camera module. The camera module may include a second board for the camera module, which may include a second electrode and a housing to accommodate the second board therein. Further, at least one lead may be electrically connected to the second electrode to penetrate through the housing. In operation S200, the camera module is mounted to the first board by connecting the lead of the camera module to the first electrode of the first board.

The camera module may be mounted to the first board using a surface-mount technology (SMT) through a reflow process or other suitable process. When using the SMT, the camera module 30 may be mounted together with other components on the first board 20 in the mounting process.

Referring to FIG. 10, operation S200, which performs the mounting of the camera s module to the first board includes, operation S210, operation S220, and operation S230. In operation 210, a solder paste containing a conductive material is applied to the first electrode S210. In operation 220, the lead is adhered to the first electrode to which the solder paste is applied. In operation S230, the solder paste is sintered at a temperature above a reference threshold.

More specifically, the solder paste may be made of the conductive material, such as lead (Pb), and may be applied to the first electrode 26 of the first board 20. The camera module 30 may be picked up by a mounting device and may be held so that the lead 40 of the camera module 30 comes in contact with the first electrode 26 on the first board 20. The first board 20 in which the camera module 30 is held may be inputted to a reflower, such that the solder paste may melt at a temperature above the reference threshold. The first electrode 26 of the first board 20 may be adhered to the lead 40.

The reflow process may be performed along with the mounting process of various components. Therefore, the camera module may be mounted along with the various components that may be mounted on the first board. In a conventional manufacturing process, an additional process may be required to mount the camera module on the first board. However, according to exemplary embodiments of the present invention, mounting of the camera module may be achieved along with mounting of other components. Accordingly, the production process of the terminal may be more simplified and production costs may be reduced.

FIG. 11 is a flowchart illustrating a manufacturing method of a terminal according to an exemplary embodiment of the present invention.

Referring to FIG. 11, the manufacturing method may be applied to a terminal in which, the first board may be formed to have the accommodation portion that opens to a side face of the first board to allow a camera module and its housing to be inserted therein. The camera module to be inserted includes a housing, which may include a first side face and a second side face opposing each other, grooves that are formed in the first side face and the second side face so as to be fitted into the accommodation portion, and the leads may be formed to be drawn to the insides of the grooves.

The mounting of the camera module to the first board in operation S200 includes operation S240, which may mount the camera module to the first board by inserting the camera module into accommodation portion of the first board.

In the terminal including the first board in which the camera module is mounted, the camera module may be mounted through a component mounting process or by an insertion method. Accordingly, the manufacturing process for the terminal may be simplified and manufacturing costs may be reduced.

In addition, since the camera module is connected to the first board through the lead structure, additional margin space for preventing or reducing a likelihood of incurring noise in the camera module may be absent. Therefore, the mounting space of the camera module may be reduced so that it may be possible to reduce a size and thickness of the terminal as a whole.

In addition, since the camera module may be mounted to the first board to have a desired mounting height, a degree of design freedom or flexibility in designing of the terminals may be increased.

In addition, the leads may be mounted in a reflow method or connected to the first electrode by employing a lead structure having a specific contact structure, such that a contact failure problem may be reduced or prevented, thereby enhancing the reliability of the terminals.

Although exemplary embodiments of the present invention are described with respect to a terminal, they are not limited thereto. For example, aspects of the invention may be implemented in a mobile computing device, a stationary device with a camera module, and the like.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A terminal, comprising:
a first board comprising an accommodation portion, the accommodation portion being disposed in a first groove of the first board; and
a camera module mounted in the accommodation portion.

2. The terminal of claim 1, further comprising:
a lead to connect the first board to the camera module,
wherein the first board is connected to the lead with a first electrode and the camera module is connected to the lead with a second electrode.

3. The terminal of claim 2, wherein the camera module comprises a housing to accommodate the second electrode.

4. The terminal of claim 3, wherein sides of the housing are formed at an angle to provide a narrower width at a bottom portion of the housing disposed within the accommodation portion.

5. The terminal of claim 2, wherein the lead comprises a first sub-lead, a second sub-lead, and a main lead.

6. The terminal of claim 5, wherein the first sub-lead extends further than the second sub-lead from the camera module.

7. The terminal of claim 5, wherein the first board extends towards a vertical edge of the second sub-lead to contact a surface of the first sub-lead through a first electrode.

8. The terminal of claim 5, wherein the first board connects to at least one of the sub-leads through the first electrode.

9. The terminal of claim 5, wherein if the first board connects to the first sub-lead, a first insertion depth and a first mounting height are provided, and if the first board connects to the second sub-lead, a second insertion depth and a second mounting height are provided.

10. The terminal of claim 5, wherein the first sub-lead is separated from the second sub-lead by a distance to provide a second groove therebetween.

11. The terminal of claim 1, wherein the camera module is mounted on the first board using a surface-mount technology (SMT).

12. The terminal of claim 1, wherein the camera module comprises a second groove in which a portion of the first board is insertable.

13. The terminal of claim 12, wherein the second groove accommodates a portion of the first board when the camera module is mounted on the accommodation portion.

14. The terminal of claim 12, wherein the first board is disposed in the second groove and connected a first sub-lead and a second sub-lead using a first upper electrode and a first lower electrode, respectively.

15. A method for manufacturing a terminal, comprising:
obtaining a first board comprising an accommodation portion, the accommodation portion being disposed in a first groove of the first board;
obtaining a camera module mounted in the accommodation portion; and
mounting the camera module in the accommodation portion.

16. The method of claim 15, wherein the camera module is mounted using a surface-mount technology (SMT).

17. The method of claim 15, wherein the mounting the camera module comprises:
applying a solder paste to a first electrode of the first board;
adhering a lead of the camera module to the first electrode; and
sintering the solder paste.

18. The method of claim 15, wherein the lead comprises a first sub-lead, a second sub-lead, and a main lead.

19. The method of claim 18, wherein the first sub-lead extends farther from the second sub-lead from the camera module.

20. A terminal, comprising:
a first board comprising an accommodation portion and a first electrode, the accommodation portion being disposed in a groove of the first board;
a camera module comprising a second electrode mounted in the accommodation portion; and
a lead to connect the first electrode of the first board to the second electrode of the camera module.
